(19) United States
(12) Patent Application Publication
(10) Pub. No.: US 2006/0141766 A1
(43) Pub. Date: Jun. 29, 2006

(54) Method of manufacturing semiconductor device

(75) Inventor: Jae Heon Kim, Icheon-si (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/159,225

(22) Filed: Jun. 23, 2005

(30) Foreign Application Priority Data
Dec. 29, 2004 (KR) 2004-114948

(51) Int. Cl. H01L 21/4763

(52) U.S. Cl. 438/624; 438/638; 438/640; 438/717; 438/634

(57) ABSTRACT

A method of manufacturing a semiconductor device in which an etching process for forming a M1 trench for a bit line is stopped on a nitride etch-stop film and the bit line is formed on the nitride film.

### BACKGROUND

1. Field of the Invention

The present invention relates to a method of manufacturing semiconductor devices. More specifically, the present invention relates to a method of manufacturing NAND flash memory.

2. Discussion of Related Art

Generally, in the process of forming a metal line of a semiconductor device, an etch-stop film for defining an etch-stop time point is formed in an etch process for defining the metal lines.

If over-etch is performed in the etch process for defining the metal lines, however, an underlying film may be damaged. In this case, there is a disadvantage in that the semiconductor devices are degraded or even destroyed.

Accordingly, there is a need for a method in which damages given to an underlying film can be minimized even if over-etch is performed in the etch process for defining the metal lines.

### SUMMARY OF THE INVENTION

Accordingly, the present invention has been made in view of the above problems, and it is an object of the present invention to provide a method of manufacturing a semiconductor device, wherein damages to underlying film qualities can be minimized even in case of an over-etch in an etch process for defining the metal line.

To achieve the above object, according to an aspect of the present invention, there is provided a method of forming a metal line of a semiconductor device, including the steps of sequentially forming a first etch-stop film, a first interlayer insulating film, a second interlayer insulating film, a second etch-stop film, a buffer oxide film, and a first hard mask conductive film on a semiconductor substrate in which a first junction region is formed; patterning the above result until the first etch-stop film is exposed to form a contact hole through the first junction region; patterning the first etch-stop film using the patterned film qualities as an etch mask; forming the same conductive film as the first hard mask conductive film on the resulting surface, and performing a polishing process to define a contact plug until the buffer oxide film is exposed; sequentially forming a third interlayer insulating film, a second hard mask conductive film, and an anti-reflection film on the resulting surface including the contact plug; patterning the anti-reflection film to define a region where a trench will be formed, and at the same time, forming an anti-reflection film having the profile of a trapezoid shape; patterning the hard mask using the anti-reflection film having a trapezoid shaped profile as an etch mask; patterning the above results until the second etch-stop film is exposed, thus defining a trench through which the contact plug is exposed; patterning the second etch-stop film using the patterned film qualities as an etch mask; and forming the same conductive film as the second hard mask conductive film on the resulting surface, and performing a polishing process to define a metal line until the third interlayer insulating film is exposed.

In embodiments, the first hard mask conductive film is a polysilicon film.

In embodiments, the second hard mask conductive film is a tungsten film.

In embodiments, the patterning process of the anti-reflection film having a trapezoid shaped profile is performed using an etch process using HBr gas.

In embodiments, the patterning process of the hard mask is an etch process that is performed using a compound formed of a combination of SF₆, Cl₂, O₂, BCl₃ and N₂.

In embodiments, the etch process that is performed only until the second etch-stop film is exposed is performed using one of a mixed gas of C₄F₈, CH₂F₂, Ar and O₂, a mixed gas of C₄F₈, CH₂F₂ and Ar, a mixed gas of C₅F₈, Ar and O₂, and a mixed gas of C₅F₈, Ar and O₂CH₂F₂.

In embodiments, in the process of polishing the polysilicon film, which is performed until the buffer oxide film is exposed, is performed until the polysilicon film hard mask is removed.

In embodiments, in the process of polishing the tungsten film, which is performed until the second etch-stop film is exposed, is performed until the tungsten film hard mask is removed.

### BRIEF DESCRIPTION OF THE DRAWINGS

FIGS. 1 to 7 are cross-sectional views for explaining a method of forming a metal line of a semiconductor device according to an embodiment of the present invention, and

FIGS. 8 and 9 are cross-sectional views for explaining a method of forming a metal line of a semiconductor device according to an embodiment of the present invention.

### DETAILED DESCRIPTION OF PREFERRED EMBODIMENTS

Embodiments of the present invention will be described with reference to the accompanying drawings. Since these embodiments are provided so that a person of ordinary skill in the art will be able to understand the present invention, they may be modified in various manners and the scope of the present invention is not limited by the embodiments described herein.

Where one film is described as being “on” the other film or a semiconductor substrate, the one film may directly contact the other film or the semiconductor substrate. Alternatively, one or more films may be intervened between the one film and the other film or the semiconductor substrate. Furthermore, in the drawing, the thickness and size of each layer are exaggerated for convenience of explanation and clarity. Like reference numerals are used to identify the same or similar parts.

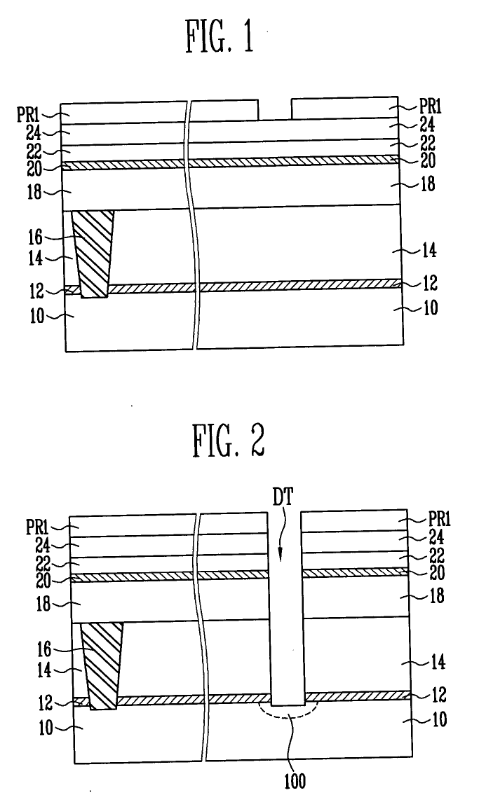

FIGS. 1 to 7 are cross-sectional views for explaining a method of forming a metal line of a semiconductor device according to an embodiment of the present invention.

Referring first to FIG. 1, a plurality of isolation films (not shown), which are parallel to each other, is formed in predetermined regions on the semiconductor substrate 10 to define an active region. A NAND flash memory device is largely divided into a cell region (not shown) and a peripheral region (not shown). The cell region consists of a plurality of strings, wherein a source select transistor (not shown), a plurality of memory cells (not shown) and a drain select transistor (not shown) are connected in a serial manner in each string. The peripheral region (not shown) has peripheral transistors formed in.

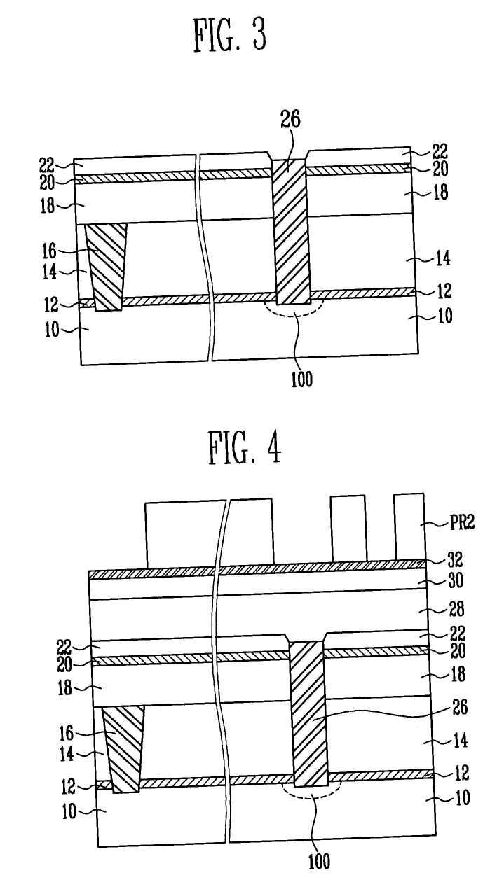

An ion implant process is performed on the entire structure having the formed transistors and the memory cells, whereby a source region (not shown) is formed within the semiconductor substrate on one side of the source select transistor, a drain region 100 (See FIG. 2) is formed within the semiconductor substrate on one side of the drain select transistor, and an impurity region (not shown) is formed between the memory cells.

A first etch-stop film 12 and a first interlayer insulating film 14 are formed on the entire structure. A source contact plug 16 through which the source region is exposed is also formed.

A second interlayer insulating film 18, a second etch-stop film 20, a buffer oxide film 22 and a polysilicon film 24 for a hard mask are sequentially formed on the entire structure including the source contact plug 16.

A polysilicon film 24 is used as a hard mask for a patterning process. The polysilicon film 24 is formed for securing a margin when an etch process is performed on a photoresist that will be formed on a hard mask later on. The polysilicon film 24 is also formed so that it can be removed at the same time in a polishing process such as an etch-back process, which is carried out after a polysilicon film 24 is buried within a subsequent contact hole.

A first photoresist pattern PR1 for forming a drain contact plug is formed on a predetermined region of the polysilicon film 24 for a hard mask.

Referring next to FIG. 2, an etch process is performed using the formed first photoresist pattern PR1 as an etch mask until the underlying first etch-stop film 12 is exposed.

An etch process is then performed on the exposed first etch-stop film 12 using the etched film as an etch mask, thus forming a drain contact hole DT through which the drain region 100 is exposed.

As the etch process on the first etch-stop film is performed after the etch process stopped in the first etch-stop film, uniform contact resistance can be implemented so that loss of the semiconductor substrate can be minimized.

Referring to FIG. 3, a polysilicon film is formed on the resulting surface in which the drain contact hole DT is formed. A planarization process, such as an etch-back process, is then performed until the buffer oxide film 22 is exposed, thereby forming a drain contact plug 26.

In this case, in the etch-back process, a topology is given among insulating films adjacent to the polysilicon film within the drain contact plug.

In the etch-back process for forming the drain contact plug 26, an underlying hard mask up to and including the polysilicon film 24 is removed.

Referring to FIG. 4, a third interlayer insulating film 28, a tungsten film 30 for a hard mask, and an anti-reflection film 32 are sequentially formed on the resulting surface including the drain contact plug 26.

A second photoresist pattern PR2 for defining a metal line is formed on the anti-reflection film 32. The reason why the hard mask is formed using the tungsten film is for allowing the tungsten film to be removed simultaneously with a planarization process, which is performed after tungsten is buried in a subsequent trench.

Referring to FIG. 5, the anti-reflection film 32 is etched using the formed second photoresist pattern PR2 as an etch mask, thereby forming an anti-reflection film 32 having a trapezoid shaped profile.

If a HBr gas is used in the etch process for forming the anti-reflection film 32 having the trapezoid shaped profile, polymer is generated in large quantities, and is thus deposited on the anti-reflection film pattern, so that the trapezoid shaped profile is formed.

The tungsten film hard mask 30 is patterned using the second photoresist pattern PR2 and the anti-reflection film etch mask 32 having the trapezoid shaped profile.

As the anti-reflection film having the trapezoid shaped profile is formed, the critical dimension (CD) of the tungsten film for an underlying hard mask can be increased. The etch process for patterning the the tungsten film hard mask is carried out using a compound formed of a combination of SF₆, Cl₂, O₂, BCl₃ and N₂.

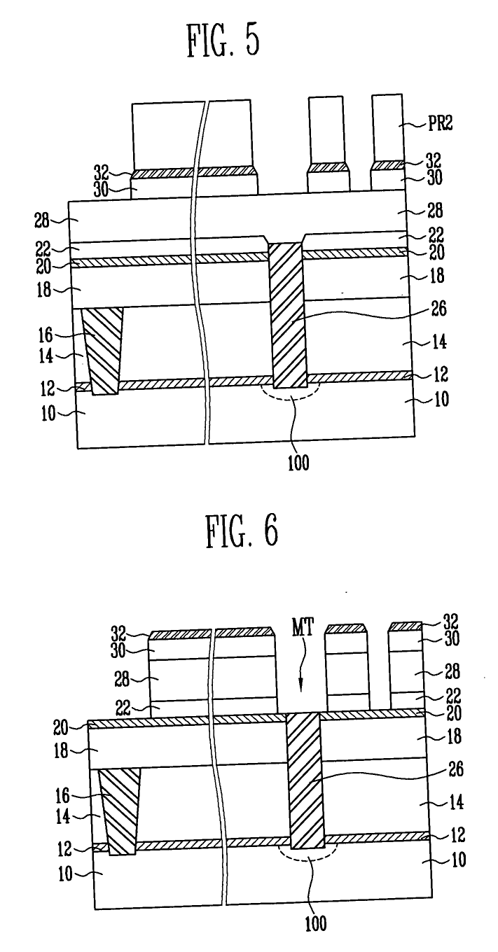

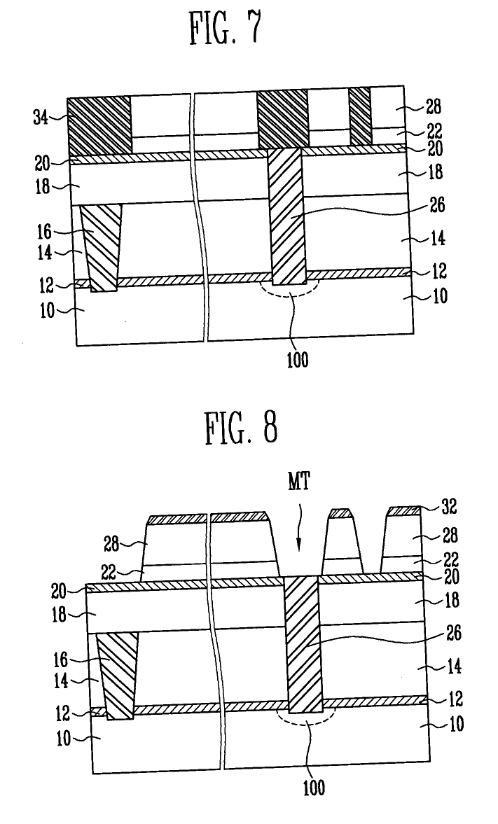

Referring to FIG. 6, an etch process is performed until the underlying second etch-stop film 20 is exposed using the patterned tungsten film hard mask 30 and the anti-reflection film etch mask 32 having the trapezoid shaped profile, thereby forming a trench MT for a bit line.

The second etch-stop film 20 remains below the trench MT. In a burial process of a conductive film for a metal line, which is a subsequent process, the conductive film for the metal line is formed on the second etch-stop film 20.

As the trench etch process is stopped when the etch-stop film is exposed, a metal line of a uniform thickness can be implemented. Due to this, in an etch process for forming an underlying contact, a contact etch margin can be secured by applying a low thickness of an underlying oxide film.

The etch process, which is performed until the second etch-stop film is exposed, is performed using a process having a high selective ratio against the interlayer insulating film and the etch-stop film being the oxide films. In this case, the performed etch process is performed using a mixed gas of C₄F₈, CH₂F₂, Ar and O₂, a mixed gas of C₄F₈, CH₂F₂ and Ar, a mixed gas of C₅F₈, Ar and O₂, and a mixed gas of C₅F₈, Ar and O₂CH₂F₂.

Referring to FIG. 7, a conductive film such as a tungsten film is formed on the resulting surface including the trench MT. A polishing process is performed until the third interlayer insulating film 28 is exposed, thus completing the formation process of the metal line 34.

In the polishing process that is performed after tungsten is buried in the trench, the tungsten film 30 for a hard mask can also be removed.

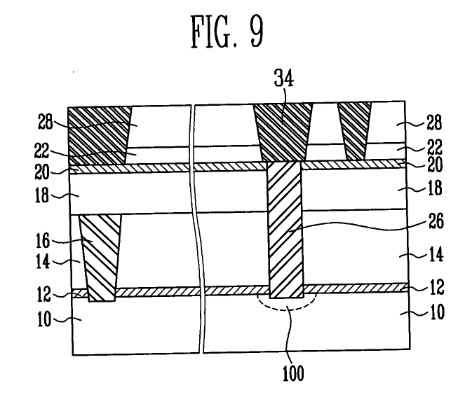

FIGS. 8 and 9 are cross-sectional views for explaining a method of forming a metal line of a semiconductor device according to an embodiment of the present invention.

Referring to FIG. 8, the second embodiment of the present invention is the same as the first embodiment until the steps of FIG. 3. A third interlayer insulating film 28 and an anti-reflection film 32 are sequentially formed on the resulting surface on which the steps of FIG. 3 are completed. A second photoresist pattern (not shown) for defining a metal line is formed on the anti-reflection film 32. The anti-reflection film 32 is etched using the formed second photoresist pattern (not shown) as an etch mask, thus forming anti-reflection films 32 having the trapezoid shaped profile.

An etch process is then performed using the anti-reflection film 32 having the trapezoid shaped profile and the second photoresist pattern as an etch mask until the underlying second etch-stop film 20 is exposed, thereby forming a trench MT.

By using the anti-reflection film 32 having the trapezoid shaped profile and the second photoresist pattern as the etch mask, the third interlayer insulating film 28 and the buffer oxide film 22 are patterned to have a slope.

The second etch-stop film 20 remains below the trench MT. In a burial process of a conductive film for a metal line, which is a subsequent process, the conductive film for the metal line is formed on the second etch-stop film. In this case, in order for the formed drain contact plug 26 and the subsequently formed metal line to be in contact with each other, a process of removing the second etch-stop film 20 formed on the drain contact plug is performed.

Referring to FIG. 9, a conductive film such as a tungsten film is formed on the entire surface including the trench MT. A polishing process is then performed until the third interlayer insulating film 28 is exposed, thereby completing the formation process of the metal line 34.

As described above, according to the present invention, etch for forming a trench and a contact hole is performed only until an etch-stop film is exposed. Thus, although over-etch occurs in an etch process for defining a metal line, damages given to an underlying insulating film can be minimized. Further, as an anti-reflection film having the profile of a trapezoid shape is included, DICD (Development Inspection Critical Dimension) can be increased after development and a photoresist margin can also be secured accordingly.

Furthermore, as formation of a film quality can be omitted to prevent damages of underlying insulating films, a sufficient width of a metal line can be secured. Accordingly, there are effects in that the number of a process can shorten, and cost can be saved.

Moreover, since etch for forming a trench and a contact hole is performed only until an etch-stop film is exposed, a depth of the trench and the contact hole can be controlled to a predetermined value. Thus, an insulating film where the trench and the contact hole are formed can be formed to a desired height, and an etch margin for the insulating film can also be secured.

Although the foregoing description has been made with reference to the above embodiments, it is to be understood that changes and modifications of the present invention may be made by a person of ordinary skilled in the art without departing from the spirit and scope of the present invention and appended claims.

What is claimed is:

1. A method of manufacturing a semiconductor device, comprising:
(a) sequentially forming a first etch-stop film, a first interlayer insulating film, a second interlayer insulating film, a second etch-stop film, a buffer oxide film, and a first hard mask conductive film on a semiconductor substrate in which a first junction region is formed;
(b) performing an etching process until the first etch-stop film is exposed to form a contact hole;
(c) removing the exposed first etch-stop film to expose the first junction region;
(d) forming the same conductive film as the first hard mask conductive film on the resulting surface, and performing a first planarization process to define a contact plug until the buffer oxide film is exposed;
(e) sequentially forming a third interlayer insulating film, a second hard mask conductive film, and an anti-reflection film on the resulting surface including the contact plug;
(f) patterning the anti-reflection film to define a region where a trench will be formed, and at the same time to form an anti-reflection film having a trapezoid shaped profile;
(g) patterning the hard mask using the anti-reflection film having the trapezoid shaped profile as an etch mask;
(h) performing an etching process until the second etch-stop film is exposed so that a trench is formed; and
(i) forming the same conductive film as the second hard mask conductive film on the resulting surface, and performing a second planarization process to define a metal line until the third interlayer insulating film is exposed.

2. The method as claimed in claim 1, wherein the first hard mask conductive film is a polysilicon film.

3. The method as claimed in claim 1, wherein the second hard mask conductive film is a tungsten film.

4. The method as claimed in claim 1, wherein the patterning process of the anti-reflection film having the trapezoid shaped profile is performed using an etch process using HBr gas.

5. The method as claimed in claim 1, wherein the patterning process of the hard mask is performed using a compound formed of a combination of SF₆, Cl₂, O₂, BCl₃ and N₂.

6. The method as claimed in claim 1, wherein the etch process that is performed only until the second etch-stop film is exposed is performed using one of a mixed gas of C₄F₈, CH₂F₂, Ar and O₂, a mixed gas of C₄F₈, CH₂F₂ and Ar, a mixed gas of C₅F₈, Ar and O₂, and a mixed gas of C₅F₈, Ar and O₂CH₂F₂.

7. The method as claimed in claim 1, wherein the first conductive film is removed during the first planarization.

8. The method as claimed in claim 1, wherein the second conductive film is removed during the second planarization.

9. A method of forming a bit line of a NAND flash memory device, comprising:
(a) sequentially forming a first etch-stop film, a first interlayer insulating film, a second interlayer insulating film, a second etch-stop film, a buffer oxide film, and a first hard mask conductive film on a semiconductor substrate in which a first junction region is formed;
(b) performing an etching process until the first etch-stop film is exposed to form a contact hole;
(c) removing the exposed first etch-stop film to expose the first junction region;
(d) forming the same conductive film as the first hard mask conductive film on the resulting surface, and performing a first planarization process to define a contact plug until the buffer oxide film is exposed;
(e) sequentially forming a third interlayer insulating film, a second hard mask conductive film, and an anti-reflection film on the resulting surface including the contact plug;
(f) patterning the anti-reflection film to define a region where a trench will be formed, and at the same time to form an anti-reflection film having a trapezoid shaped profile;
(g) patterning the hard mask using the anti-reflection film having the trapezoid shaped profile as an etch mask;
(h) performing an etching process until the second etch-stop film is exposed so that a trench is formed; and
(i) forming the same conductive film as the second hard mask conductive film on the resulting surface, and performing a second planarization process to define a bit line until the third interlayer insulating film is exposed.

10. The method as claimed in claim 9, wherein the first hard mask conductive film is a polysilicon film.

11. The method as claimed in claim 9, wherein the second hard mask conductive film for hard mask is a tungsten film.

12. The method as claimed in claim 9, wherein the patterning process of the anti-reflection film having the trapezoid shaped profile is performed using an etch process using HBr gas.

13. The method as claimed in claim 9, wherein the patterning process of the hard mask is performed using a compound formed of a combination of SF₆, Cl₂, O₂, BCl₃ and N₂.

14. The method as claimed in claim 9, wherein the etch process that is performed only until the second etch-stop film is exposed is performed using one of a mixed gas of C₄F₈, CH₂F₂, Ar and O₂, a mixed gas of C₄F₈, CH₂F₂ and Ar, a mixed gas of C₅F₈, Ar and O₂, and a mixed gas of C₅F₈, Ar and O₂CH₂F₂.

15. The method as claimed in claim 9, wherein the first conductive film is removed during the first planarization.

16. The method as claimed in claim 9, wherein the second conductive film is removed during the second planarization.
